(19) United States
(12) Patent Application Publication
(10) Pub. No.: US 2025/0372347 A1
(43) Pub. Date: Dec. 4, 2025

(54) LOW PROFILE AND EMBEDDED GAS DIFFUSERS IN AN INDUCTIVELY COUPLED PLASMA CHAMBER EMPLOYING ANTENNA ARRAYS

(71) Applicant: Applied Materials, Inc., Santa Clara, CA (US)

(72) Inventors: Zheng John YE, Santa Clara, CA (US); Jianhua ZHOU, Campbell, CA (US); Jeevan Prakash SEQUEIRA, Milpitas, CA (US); Peter GONSALVES, Santa Clara, CA (US); Jinhyun CHO, Santa Clara, CA (US); Tae Kyung WON, San Jose, CA (US); Young Dong LEE, Hwaseong-Si (KR); Hanzheng H. LIN, Santa Clara, CA (US); Suhail ANWAR, Saratoga, CA (US); Chien-Teh KAO, Sunnyvale, CA (US)

(21) Appl. No.: 19/197,338

(22) Filed: May 2, 2025

Related U.S. Application Data
(60) Provisional application No. 63/653,645, filed on May 30, 2024.

(51) Int. Cl. H01J 37/32; C23C 16/509

(52) U.S. Cl. CPC H01J 37/3211; C23C 16/509; H01J 37/32119; H01J 37/3244; H01J 2237/3321

(57) ABSTRACT

The present disclosure is directed to an antenna array. The antenna array includes a plurality of inductive couplers, a plurality of support members, and a plurality of gas diffusion modules. The inductive couplers include a plurality of antennas disposed over a dielectric window. The plurality of support members include an interface member configured to support the dielectric window. The interface member includes a plurality of gas ports and a channel. The plurality of gas diffusion modules are disposed within the channel. The plurality of gas diffusion modules includes a body, and a plurality of gas diffusion holes.

### CROSS-REFERENCE TO RELATED APPLICATIONS

This application claims benefit of U.S. provisional patent application Ser. No. 63/653,645, filed May 30, 2024, which is herein incorporated by reference.

### BACKGROUND

### Field

Embodiments of the present disclosure generally relate to process chambers, such as high-density plasma (HDP) chambers. More particularly, embodiments of the present disclosure relate to low profile and embedded gas diffusers in inductively coupled plasma chambers.

### Description of the Related Art

In the manufacture of solar panels or flat panel displays, many processes are employed to deposit thin films on substrates, such as semiconductor substrates, solar panel substrates, and liquid crystal display (LCD) and/or organic light emitting diode (OLED) substrates, to form electronic devices thereon. The deposition is generally accomplished by introducing a precursor gas into a chamber having a substrate disposed on a temperature controlled substrate support. The precursor gas is typically directed through a gas distribution assembly disposed above the substrate support. The precursor gas in the chamber is energized (e.g., excited) into a plasma by applying a single or array of radio frequency (RF) antennas inductively coupled to the precursor gas to form the plasma. The excited gas reacts to form a layer of material on a surface of the substrate that is positioned on the temperature controlled substrate support.

The size of the substrates for forming the electronic devices exceeds 1 square meter in surface area. Uniformity in film thickness across these substrates is difficult to achieve. Film thickness uniformity becomes even more difficult as the substrate sizes increase. To provide uniform thicknesses, gases can be provided to the process region in a plurality of gas distribution zones. Each of the gas distribution zones include plenums that are used to control gas distribution and plasma formation. Uniformity of plasma production, however, continues to be a challenge as substrate sizes continue to increase.

Furthermore, complications may arise where parasitic plasma is formed inside a section of the process gas passageways when the product of the pressure and the dimensions are appropriate to support the parasitic plasma of certain gas chemistry above a power threshold. In this instance, power would be absorbed by the parasitic plasma before the power is delivered to the main plasma as intended.

Accordingly, what is needed in the art is a method and apparatus for improved thickness uniformity across large substrates.

### SUMMARY

Embodiments of the present disclosure generally relate to process chambers, such as high-density plasma (HDP) chambers. More particularly, embodiments of the present disclosure relate to low profile and embedded gas diffusers in inductively coupled plasma chambers.

In one embodiment, an antenna array is disclosed. The antenna array includes a plurality of inductive couplers, a plurality of support members, and a plurality of gas diffusion modules. The inductive couplers include a plurality of antennas disposed over a dielectric window. The plurality of support members include an interface member configured to support the dielectric window. The interface member includes a plurality of gas ports and a channel. The plurality of gas diffusion modules are disposed within the channel. The plurality of gas diffusion modules includes a body, and a plurality of gas diffusion holes.

In another embodiment, an antenna array is disclosed. The antenna array includes a plurality of inductive couples, a plurality of support members, and a plurality of gas diffusion modules. The plurality of inductive couplers include a plurality of antennas disposed over a dielectric window. The plurality of support members include an interface member configured to support the dielectric window. The interface member includes a plurality of gas ports. The plurality of gas diffusion modules are coupled to the interface member and extending less than about 12.1 mm past a lower surface of the interface member. The plurality of gas diffusion modules include a body. The body includes a plurality of gas diffusion holes.

In still other embodiments, an antenna array is disclosed. The antenna array includes a plurality of inductive couplers, a plurality of support members, and a plurality of diffusion modules. The plurality of inductive couplers include a plurality of antennas disposed over a dielectric window. The plurality of support members include an interface member configured to support the dielectric window. The interface member includes a plurality of gas ports. The plurality of gas diffusion module are coupled to the interface member and include a body and gas diffusion tubes. The gas diffusion tubes include a plurality of gas diffusion holes.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 illustrates a cross sectional side view of a processing chamber, according to embodiments of the disclosure.

FIG. 2A illustrates a schematic, cross-sectional perspective view of a portion of an antenna array with a gas diffusion module embedded in an interface member, according to embodiments.

FIG. 2B illustrates a schematic, bottom view of a portion of the antenna array with the gas diffusion module embedded in the interface member, according to embodiments.

FIG. 2C illustrates a schematic cross-sectional side view of a portion of the antenna array with the gas diffusion module embedded in the interface member, according to embodiments.

FIG. 2D illustrates a bottom perspective view of a portion of the antenna array with the gas diffusion module embedded in the interface member, according to embodiments.

FIG. 3 illustrates a top plan view of an antenna of an inductive coupler, according to embodiments of the disclosure.

FIG. 4 illustrates a schematic perspective view of a portion an antenna sub-array of the antenna array, according to embodiments of the disclosure.

FIG. 5A illustrates a schematic, cross-sectional perspective view of a portion of an antenna array with a gas diffusion module coupled to an interface member, according to embodiments of the disclosure.

FIG. 5B illustrates a schematic, bottom view of a portion of the antenna array with the gas diffusion module coupled to an interface member, according to embodiments of the disclosure.

FIG. 5C illustrates a schematic cross-sectional side view of a portion of the antenna array with the gas diffusion module coupled to an interface member, according to embodiments of the disclosure.

FIG. 5D illustrates a bottom perspective view of a portion of the antenna array with the gas diffusion module coupled to an interface member, according to embodiments of the disclosure.

FIG. 6A illustrates a schematic, cross-sectional perspective view of a portion of an antenna array with a beveled gas diffusion module coupled to an interface member, according to embodiments of the disclosure.

FIG. 6B illustrates a schematic, bottom view of a portion of the antenna array with the beveled gas diffusion module, according to embodiments of the disclosure.

FIG. 6C illustrates a schematic cross-sectional side view of a portion of the antenna array with the beveled gas diffusion module, according to embodiments of the disclosure.

FIG. 6D illustrates a bottom perspective view of a portion of the antenna array with the beveled gas diffusion module, according to embodiments of the disclosure.

FIG. 7A illustrates a schematic, cross-sectional perspective view of a portion of an antenna array with a rounded gas diffusion module coupled to an interface member, according to embodiments of the disclosure.

FIG. 7B illustrates a schematic, bottom view of a portion of the antenna array with the rounded gas diffusion module, according to embodiments of the disclosure.

FIG. 7C illustrates a schematic cross-sectional side view of a portion of the antenna array with the rounded gas diffusion module, according to embodiments of the disclosure.

FIG. 7D illustrates a bottom perspective view of a portion of the antenna array with the rounded gas diffusion module, according to embodiments of the disclosure.

FIG. 8 illustrates a bottom perspective view of a portion of the antenna array with the interface tube gas diffusion module coupled to the interface member, according to embodiments of the disclosure.

FIG. 9 illustrates a bottom perspective view of a portion of the antenna array with the window tube gas diffusion module coupled to the interface member, according to embodiments of the disclosure.

FIG. 10 illustrates a bottom perspective view of a portion of the antenna array with the processing region tube gas diffusion module coupled to the interface member, according to embodiments of the disclosure.

FIG. 11 illustrates a control schematic for use within the processing chamber, according to embodiments of the disclosure.

FIG. 12 is a block flow diagram of a method of depositing films over a substrate, according to embodiments of the disclosure.

FIG. 13 illustrates a hexagonal antenna array having hexagonal antennas, according to embodiments of the disclosure.

FIG. 14 illustrates a triangular antenna array having triangular antennas, according to embodiments of the disclosure.

FIG. 15 illustrates a schematic cross-sectional side view of a portion of the antenna array with the gas diffusion module embedded in the interface member and having perpendicular diffusion holes, according to embodiments of the disclosure.

FIG. 16 illustrates a schematic cross-sectional side view of a portion of the antenna array with the gas diffusion module embedded in the interface member and having angled gas diffusion hole, according to embodiments of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to process chambers, such as high-density plasma (HDP) chambers. More particularly, embodiments of the present disclosure relate to low profile and embedded gas diffusers in inductively coupled plasma chambers.

Herein, a plurality of interface members are configured to flow gas therethrough and into a processing volume of a chamber in a number of independently controlled zones. In order to improve the uniformity of the processing of the surface of a substrate exposed to the gas in the processing zone, a gas diffusion module is embedded into the interface members or, alternatively, has a low profile and plasma passageways to allow the plasma to flow throughout the processing volume. The processing zone is configured to allow processing gas(es) to be flowed thereinto and distributed to result in a relatively uniform flow rate, or in some cases tailored flow rate, of the gases into the processing volume. An inductive coupler, such as a radiofrequency (RF) antenna, is positioned proximate to the dielectric window, and the inductive coupler inductively couples energy through the dielectric window to strike and support a plasma in the processing volume. The flow of the process gas(es) in each zone is controlled to result in uniform or tailored gas flows to achieve desired process results on the substrate.

Embodiments of the disclosure include a high density plasma chemical vapor deposition (HDP CVD) processing chamber that is operable form one or more layers or films on a substrate. The films may include, but are not limited to, silicon oxide, silicon nitride, silicon oxide-nitride, single crystal line silicon, amorphous silicon, or a combination thereof. The thickness of the films may be from about 1 micron to about 10 Å. The processing chamber as disclosed herein is adapted to deliver energized species of a precursor gas that are generated in a plasma. The plasma may be generated by inductively coupling energy into a gas under vacuum. It is to be understood that the embodiments discussed herein may be practiced in other chambers capable of providing high density plasma.

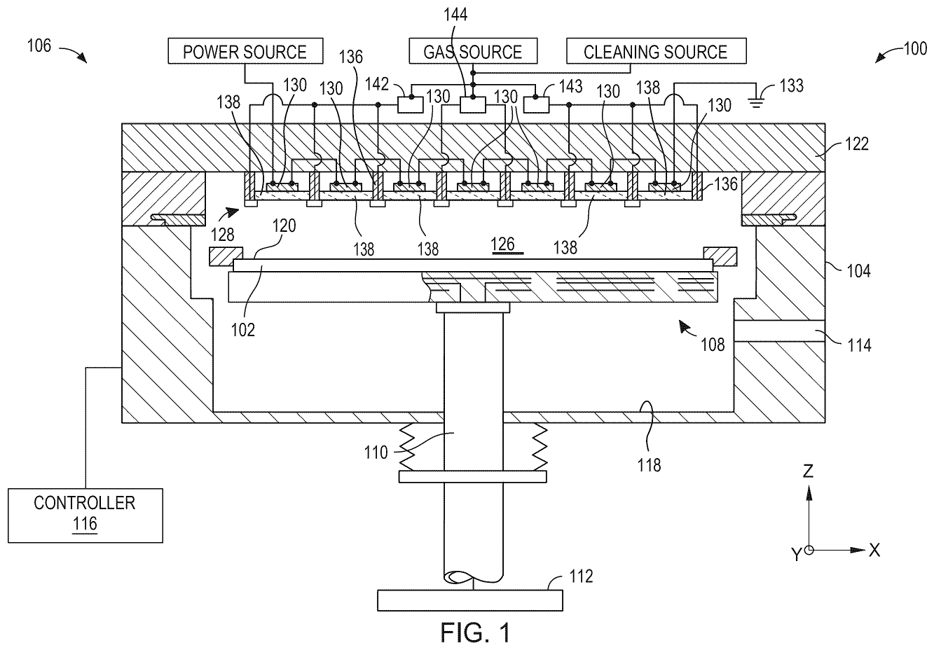

FIG. 1 illustrates a cross sectional side view of a processing chamber 100, according to one embodiment of the present disclosure. A substrate 102 is shown on a substrate surface 120 within a chamber body 104. In one embodiment, the substrate 102 includes a dielectric material (e.g., SiO₂, SiOₓN_{y}), a semiconductive material (e.g., silicon or doped silicon), a barrier material (SiNₓ, Si OₓN_{y}), or a combination thereof. The processing chamber 100 also includes a lid assembly 106, a bottom 118 disposed opposite the lid assembly 106, and a pedestal or substrate support assembly 108 disposed between the lid assembly 106 and the bottom 118. The lid assembly 106 is disposed at an upper end of the chamber body 104, and the substrate support assembly 108 is at least partially disposed within the chamber body 104. The substrate support assembly 108 is coupled to a shaft 110. The shaft 110 is coupled to a drive 112 that moves the substrate support assembly 108 vertically (in the Z direction) within the chamber body 104. The substrate support assembly 108 of the processing chamber 100 shown in FIG. 1 is in a processing position. However, the substrate support assembly 108 may be lowered in the Z direction to a position adjacent to a transfer port 114.

The lid assembly 106 may include a backing plate 122 that rests on the chamber body 104. The lid assembly 106 also functions as a plasma source 128. To function as the plasma source 128, the lid assembly 106 includes one or more inductively coupled plasma generating components, or inductive coupler 130. Each of the one or more inductive couplers 130 may be a single inductive coupler 130, two inductive couplers 130, or more than two inductive couplers 130, are simply described as inductive couplers 130 hereafter. Each of the one or more inductive couplers are coupled across a power source and ground 133. Although FIG. 1 depicts each of the inductive couplers 130 connected to the power source and ground 133 in series, a connection in parallel is also contemplated such that each inductive coupler 130 is connected and controlled independently to the power source and ground 133. In some embodiments, ground 133 is a capacitor. The power source includes a match circuit or a tuning capability for adjusting electrical characteristics of the inductive couplers.

Each of the dielectric windows 138 are supported by the support member 136. Each of the one or more inductive couplers or portions of the one or more inductive couplers are positioned on or over a respective dielectric window 138. Each of the one or more inductive couplers 130 is configured to create an electromagnetic field that energizes a process gases into a plasma in the processing region 126 as gas is flowing into the processing region 126. In some embodiments, process gases from the gas source are provided to the processing region 126 via conduits in the support members 136. The volume or flow rate of gas(es) entering and leaving the processing region 126 are controlled in different zones of the processing region 126. Zone control of processing gases is provided by a plurality of flow controllers, such as mass flow controllers 142, 143 and 144. For example, the flow rate of gases to peripheral or outer zones of the processing region 126 is controlled by the mass flow controllers 142, 143, while the flow rate of gases to a central zone of the processing region 126 is controlled by the mass flow controller 144. When chamber cleaning is required, cleaning gases from a cleaning gas source is flowed to the processing region 126 within which the cleaning gases are energized into ions, radicals, or both. The energized cleaning gases flow into the processing region 126 in order to clean chamber components. In one embodiment, the process gas(es) includes argon (Ar), nitrogen (N₂), nitrogen dioxide (NO₂), helium (He), oxygen (O₂), carbon dioxide (CO₂), hydrogen (H₂), ammonia (NH₃), phosphine, nitrogen trifluoride (NF₃), ammonia (NH₃), fluorine (F₂), sulfur hexafluoride (SF₆), silane (SiH₄), tetraethyl orthosilicate (TEOS), water vapor (H₂O), or a combination thereof.

The processing chamber 100 further includes a controller 116. The controller 116 is in communication with the processing chamber 100 and is used to control processes of the processing chamber 100. The processing chamber 100 includes a plurality of sensors (not shown) disposed therein for measures parameters such as temperature, gas flow, deposition rate, and power.

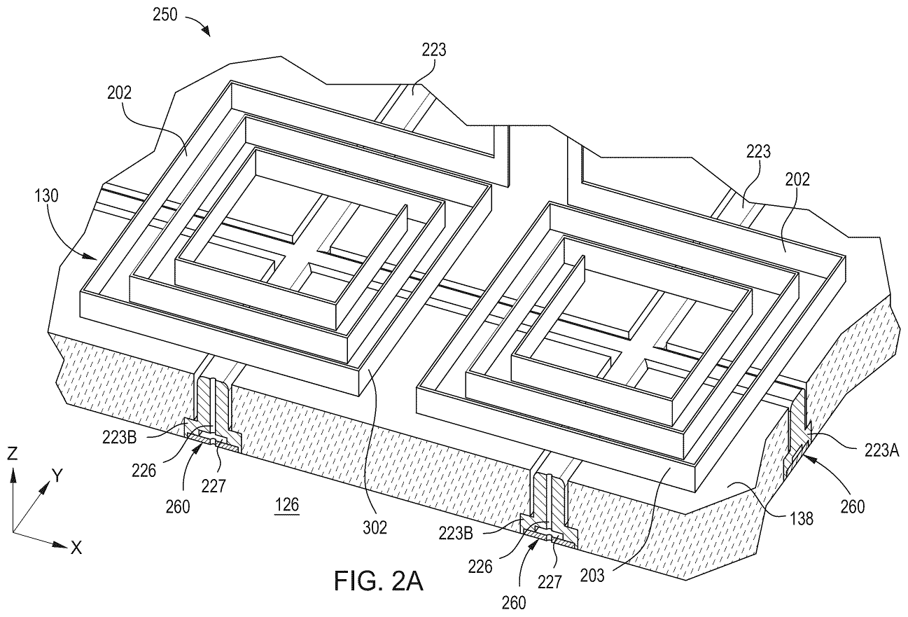

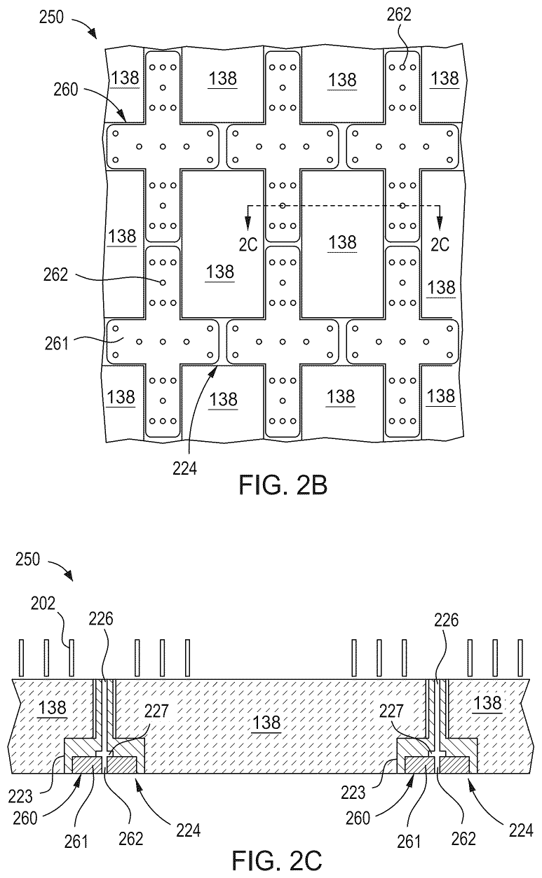

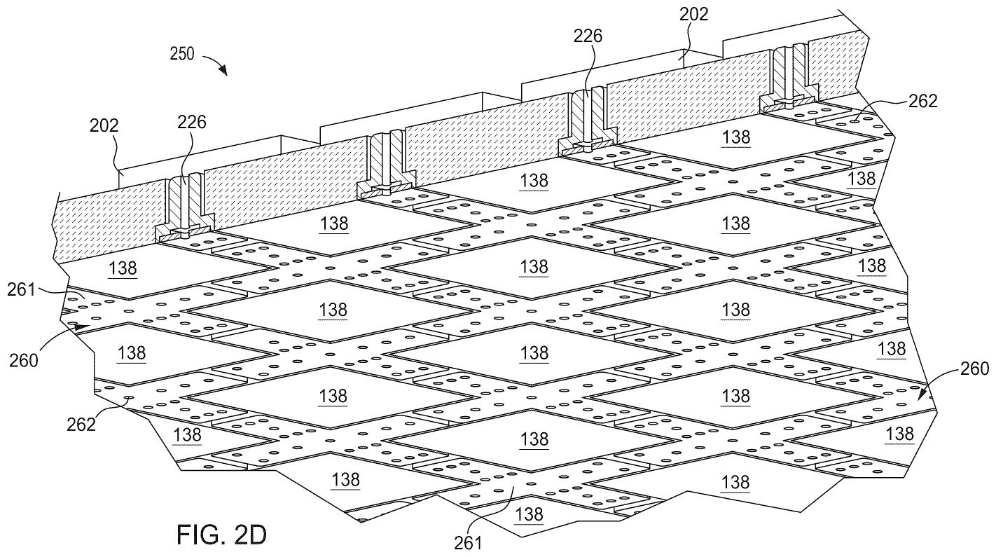

FIG. 2A illustrates a schematic, cross-sectional perspective view of a portion of an antenna array 250 with a gas diffusion module 260 embedded in an interface member 223. FIG. 2B illustrates a schematic, bottom view of a portion of the antenna array 250 with the gas diffusion module 260 embedded in the interface member 223. FIG. 2C illustrates a schematic cross-sectional side view of a portion of the antenna array 250 with the gas diffusion module 260 embedded in the interface member 223. FIG. 2D illustrates a bottom perspective view of a portion of the antenna array 250 with the gas diffusion module 260 embedded in the interface member 223.

Each inductive coupler 130 includes an antenna 202 disposed proximate to one or more corresponding dielectric windows 138 and coupled to a distribution line coupled to a matching network (e.g., power source). In some embodiments, each antenna 202 is disposed over and at least partially surrounds interfaces of adjacent dielectric windows 138. Each antenna 202 is disposed over one or more dielectric windows 138 such that a first base portion 203 and a second base portion 302 are positioned over the dielectric windows 138. The first base portions 203 are oriented at an angle relative to the second base portions 302, such as perpendicular to second base portion 302 and disposed along an X-axis. The second base portions 302 are shown along a Y-axis. Each of the second base portions 302 are parallel with respect to one another and each of the first base portions 203 are parallel with respect to one another.

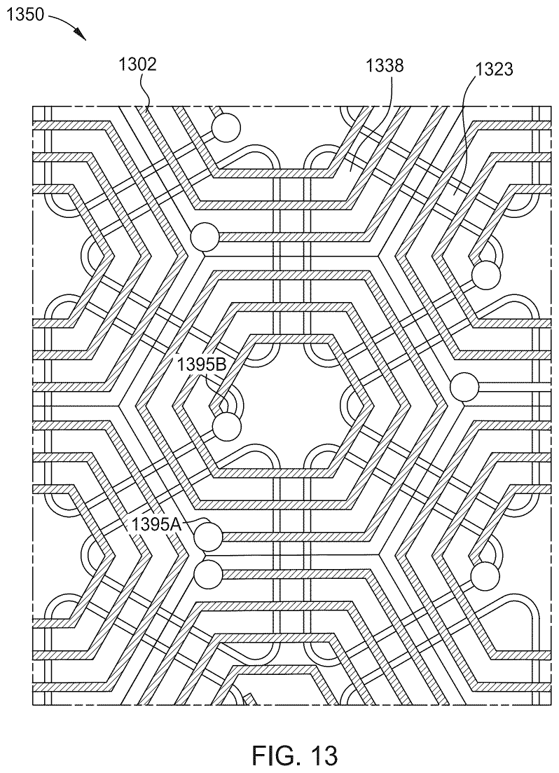

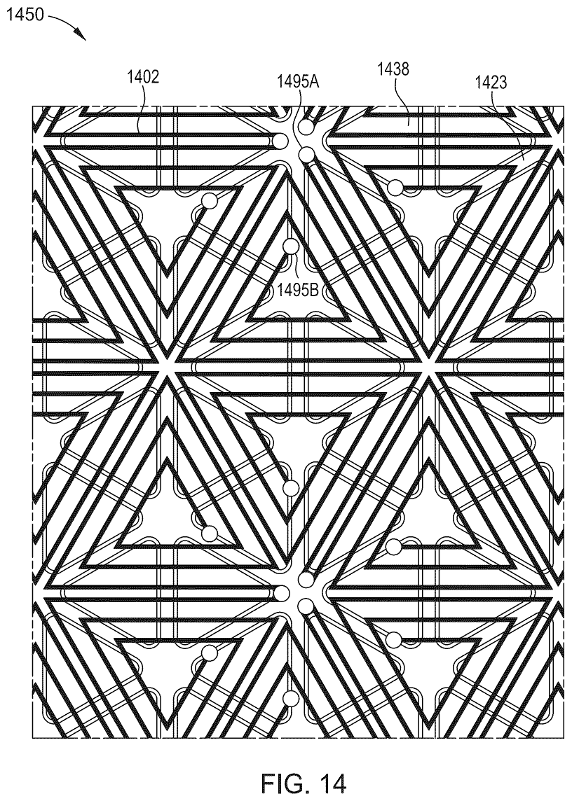

In the illustrated embodiment, the support members 136 include interface members 223 to form a grid to support a portion of the perimeter or the edge of the dielectric window 138. Each interface member 223 includes a ledge or shelf that supports a portion of the perimeter or an edge of the dielectric window 138. This grid creates longitudinal interface members 223A and latitudinal interface members 223B. The longitudinal interface member 223A is perpendicular with the second base portions 302 of the antenna 202. The latitudinal interface members 223B is perpendicular with the first base portions 203 of the antenna 202. Other additional portions are also contemplated to form alternative shapes and angles relative to one another, such as a hexagonal antenna (as shown in FIG. 13) or a triangular antenna (as shown in FIG. 14). Angles between portions can be about 60 degrees to about 170 degrees, such as about 80 degrees to about 120 degrees, such as about 90 degrees to about 100 degrees.

The interface member 223 includes a channel 224 and a plurality of gas ports 226. The channel 224 is configured to house the gas diffusion module 260. The gas diffusion module 260 includes a body 261 and a plurality of gas diffusion holes 262. The gas ports 226 are configured to allow gases to flow into the processing region 126 via the gas diffusion module 260 at predetermined flow rates. The gas diffusion module 260 receives the gas from the gas ports 226 and diffuses the gas into the processing region 126 via the plurality of gas diffusions holes 262 to enable increased uniformity in gas distribution throughout the processing region 126. The interface member 223 further includes a plenum 227. The plenum 227 extends along the channel 224 at an interface of the channel 224 and the gas diffusion module 260. The plenum 227 is configured to enable the distribution of the gas from the gas ports 226 to the gas diffusion holes 262.

Optionally, the plurality of gas diffusion holes 262 of the gas diffusion module 260 may be patterned such that a pattern is the same from region to region within the processing region 126. In other embodiments, the pattern may be different from region to region. In some embodiments, the gas diffusion holes 262 may be single path diffusion holes or split path diffusion holes. The each path of the split path diffusion holes has a length from the starting point of the gas diffusion hole 262 to an end point at the processing region 126. In some embodiments, the path length of each path of the split path diffusion hole may be equal. In other embodiments, the path length of each path of the split path diffusion hole may not be equal. The pattern and type of gas diffusion holes 262 are optimized to promote uniform deposition of films on the substrate 102. Each of the plurality of gas diffusion holes 262 further has a diameter. Controlling the path length and diameter of the plurality of gas diffusion holes 262 enables the gas flow required for deposition uniformity and other film property results.

In some embodiments, which may be combined with other embodiments, a bottom surface of the body 261 of the gas diffusion module 260 does not extend past a lower surface of the interface member 223 into the processing region 126 (e.g., the gas diffusion module 260 is disposed entirely within the channel 224). Alternatively, the gas diffusion module 260 extends a distance outward from the channel 224. The distance that the gas diffusion module 260 extends past a lower surface of the interface member 223 is less than about 12.1 mm, such as less than about 6 mm, such as about 1 mm to about 6 mm. The limited extension of the bottom surface of the body 261 of the gas diffusion module 260 into the plasma processing region 126 inhibits perturbations to the gas flow and disturbances to the boundary conditions required to generate a uniform plasma at a required RF power level within the processing region 126. Thus, the limited extensions of the bottom surface of the body 261 increases the uniformity of film thickness across the substrate 102.

During processing, the processing region 126 has a vacuum pressure of about 10 mTorr to about 3 Torr. Materials for the plasma source 128 are chosen based on one or more of electrical characteristics, strength and chemical stability. The inductive couplers 130 are made of an electrically conductive material. The backing plate 122 and the support members 136 are made of a material that is able to support the weight of the supported components and atmospheric pressure load, which may include a metal or other similar material. The backing plate 122 and the support members 136 may be made of a non-magnetic material (e.g., non-paramagnetic or non-ferromagnetic material), such as an aluminum material (e.g., aluminum, aluminum oxide, aluminum nitride). The non-magnetic material forms an electrically grounded environment through which the gas may flow, which inhibits the formation of a parasitic plasma due to the lack of an electric field. The dielectric windows 138 are made of a quartz, alumina, aluminum nitride, or sapphire materials. In some embodiments, the dielectric windows 138 include a patterned conductive surface coating consisting of copper, silver, aluminum, tungsten, molybdenum, titanium, combinations thereof, or alloys thereof forming a Faraday shield.

The RF power supplied to the inductive coupler 130 is about 1 kW to about 500 KW, such as about 5 KW to about 50 KW, such as about 10 KW to about 30 KW, such as about 15 KW to about 20 kW. In some embodiments, the RF power is supplied at a frequency of about 100 KHz to about 500 MHz frequency depending on the predetermined process and operating parameters. The RF power is supplied to sustain a plasma having a plasma density of about 1×10⁹ cm⁻³ to about 10×10¹² cm⁻³.

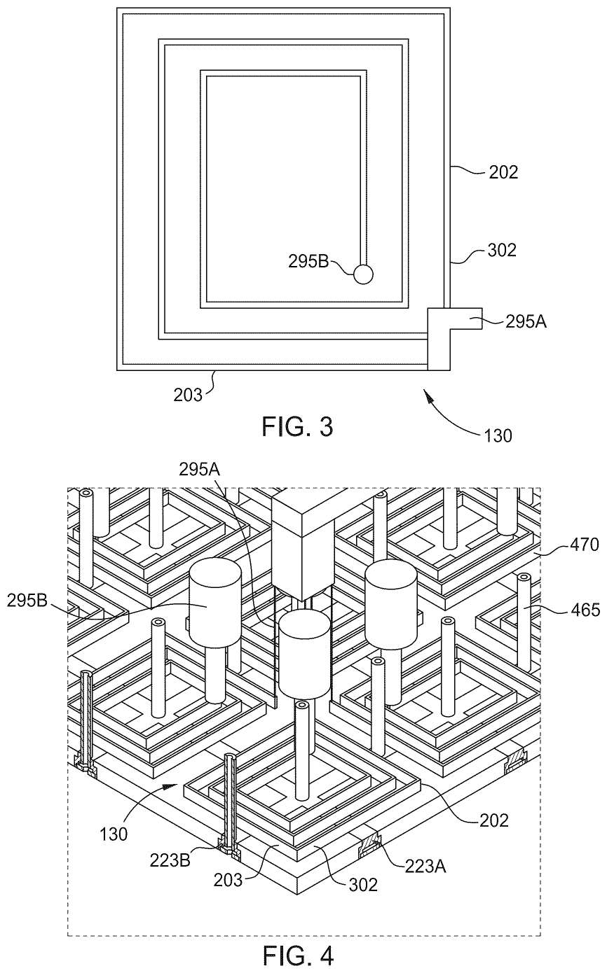

FIG. 3 illustrates a top plan view of an antenna 202 of an inductive coupler 130. The antenna 202 configuration depicts one antenna 202 that can be arranged with adjacent antennas 202 having substantially the same configuration in a pattern across the lid assembly 106. The antenna 202 includes a conductor pattern that is a rectangular spiral shape. Other spiral shapes are contemplated based on a shape the substrate, such as a triangle or a hexagon. Electrical connections include an electrical input terminal 295A and an electrical output terminal 295B. Each of the one or more inductive couplers 130 of the lid assembly 106 are connected in series and/or in parallel. The electrode shape is selected based on the shape of the base of the antenna, such as first and second base portions 203 and 302. In one example, the electrode shape is a rounded L shaped with portions that are angled relative to the second base portions 302, such as substantially perpendicular to second base portions 302, and with electrode portions that are angled relative to the first base portions 203, such as substantially perpendicular to first base portions 203.

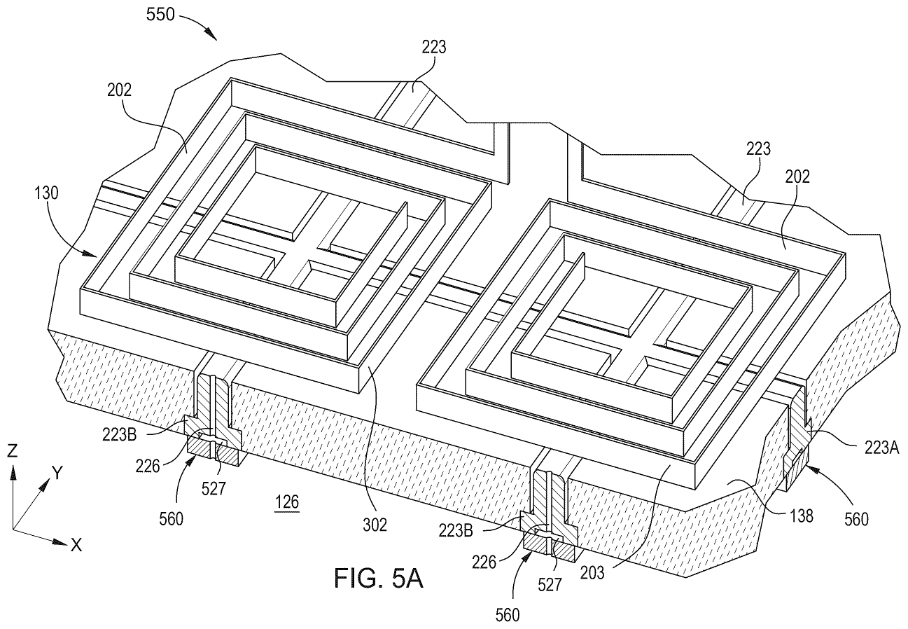

FIG. 4 illustrates a schematic, perspective view of an antenna sub-array 470 of the antenna array 250. The antenna array 250 includes a plurality of gas conduits 465. The gas conduits 465 enables the flow of the process gas from the gas source through the support members 136, interface members 223, and gas diffusion module 260 to the processing region 126. In the illustrated embodiment, the gas conduits 465 are positioned in the center of each antenna 202 and between the second base portions 302 of adjacent antennas 202. In other embodiments, however, other gas conduit 465 positions are also contemplated.

The lid assembly 106 having the inductive coupler 130 described herein can be used for HDP process chambers. The antennas 202 of the inductive coupler 130 are capable of controlling a degree of ICP coupling to the plasma at a variety of RF powers. The antennas 202 can be a helix type RF coil of either vertical or flat spiral coils of concentric or rectangular shapes, and of non-flat or vertical shapes, such as a rectangular coil, a hexagonal coil, or a triangular coil. The adjacent coil portions are arranged to locally drive plasma and to interfere or cancel RF magnetic fields generated in order to control constructive or destructive coupling based on coil design. In the illustrated embodiment, the rectangular antenna 202 has 3 turns. However, greater or lesser turns are anticipated.

The antennas 202 of the antenna sub-arrays 470 are assembled in a symmetrical fashion, where each of the antennas 202 is a mirror image of the adjacent antenna 202, and each antenna sub-array 470 is a mirror image of the adjacent sub-array 470. Therefore, the currents flowing along an of the first base portion 203 or second base portion 302 of an antenna 202 has a mirror image from the adjacent antenna 202. As a result, all of the adjacent antennas 202 and antenna sub-arrays 470 have equivalent currents in both magnitude and direction, e.g., in phase. Further, the electromagnetic fields produced by the antennas 202 and antenna sub-arrays 470 are enhanced due to constructive (e.g., in-phase) interference, with the highest magnetic field occurring at the interfaces between the antenna sub-arrays 470.

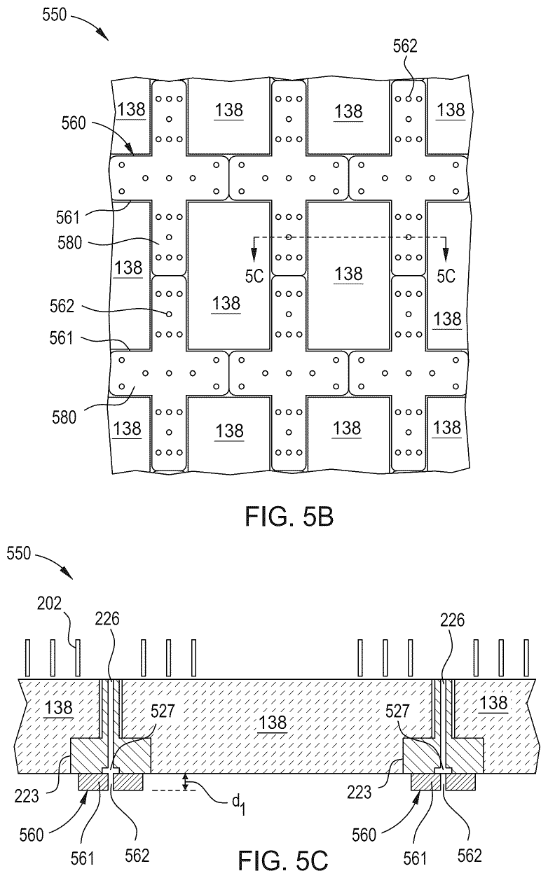

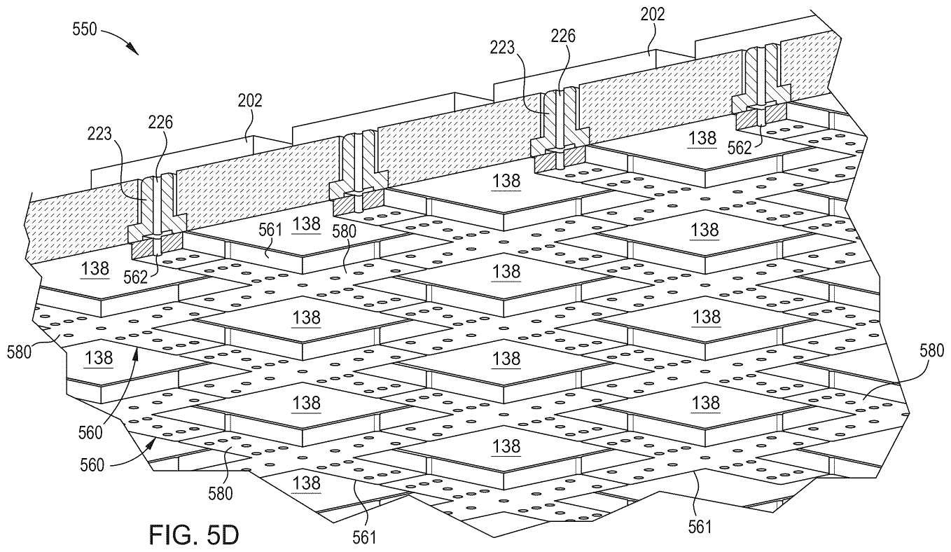

FIG. 5A illustrates a schematic, cross-sectional perspective view of a portion of an antenna array 550 with a gas diffusion module 560 coupled to an interface member 223. FIG. 5B illustrates a schematic, bottom view of a portion of the antenna array 550 with the gas diffusion module 560. FIG. 5C illustrates a schematic cross-sectional side view of a portion of the antenna array 550 with the gas diffusion module 560. FIG. 5D illustrates a bottom perspective view of a portion of the antenna array 550 with the gas diffusion module 560. The antenna array 550 may be used in place of the antenna array 250.

The gas diffusion module 560 includes a body 561 having extensions 580. The extensions 580 extend along (e.g., adjacent to) the interface members 223. The gas diffusion modules 560 are coupled to a bottom surface of the interface members 223. The gas diffusion module 560 extends a first distance d₁ away from the interface member 223 into the processing region 126. The first distance d₁ is less than about 12 mm, such as less than about 6 mm, such as about 1 mm to about 6 mm. The limited extension of the bottom surface of the gas diffusion module 560 into the plasma processing region 126 inhibits perturbations to the gas flow and disturbances to the boundary conditions required to generate a uniform plasma at a required RF power level within the processing region 126. Thus, the limited extension of the gas diffusion module 560 increases the uniformity of film thickness across the substrate 102.

The body 561 includes a plurality of gas diffusion holes 562. The gas ports 226 are configured to allow gases to flow into the processing region 126 via the gas diffusion module 560 at predetermined flow rates. The gas diffusion module 560 receives the gas from the gas ports 226 and diffuses the gas into the processing region 126 via the plurality of gas diffusions holes 562 to enable increased uniformity in gas distribution throughout the processing region 126. The interface member 223 further includes a plenum 527. The plenum 527 extends along the bottom surface of the interface member 223 at an interface of the bottom surface of the interface member 223 and the gas diffusion module 560. The plenum 527 is configured to enable the distribution of the gas from the gas ports 226 to the gas diffusion holes 562.

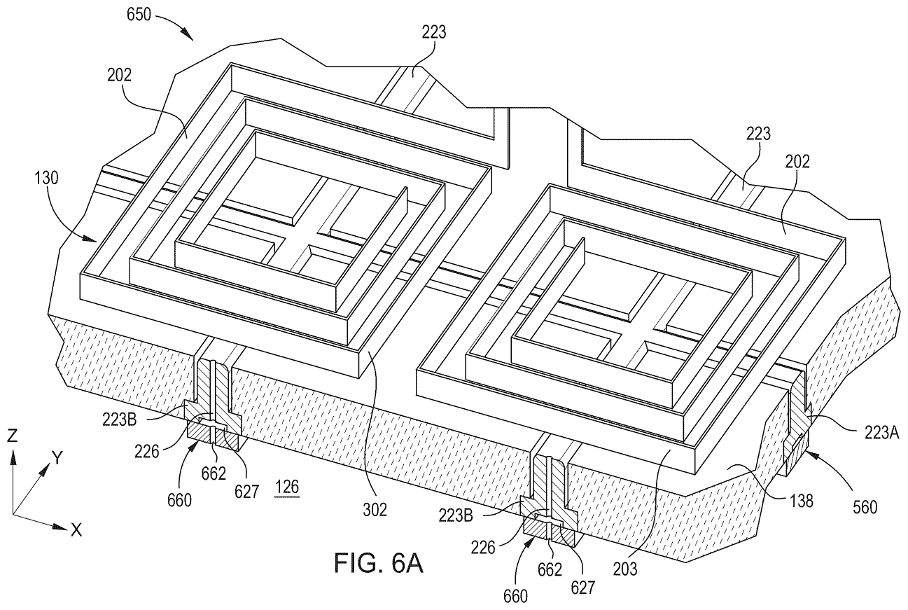

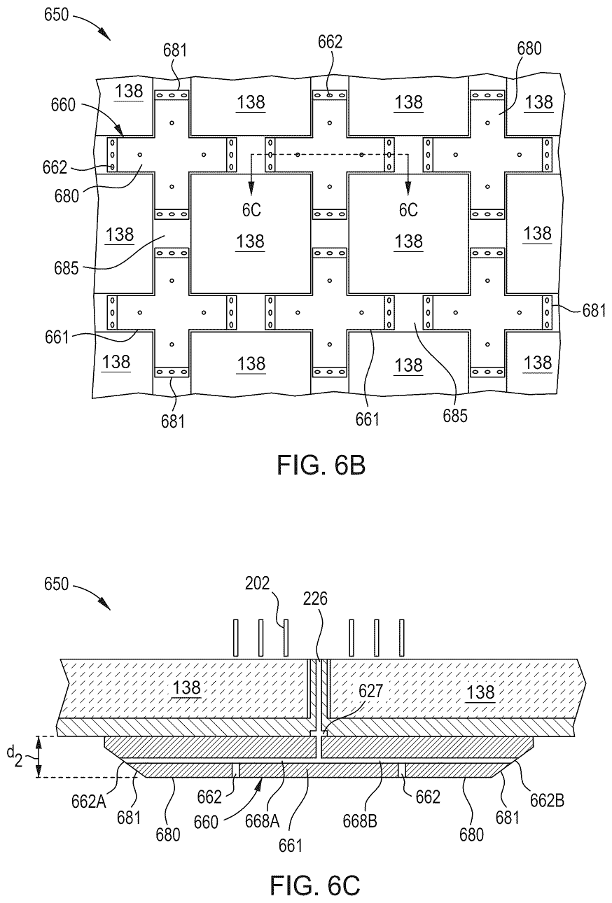

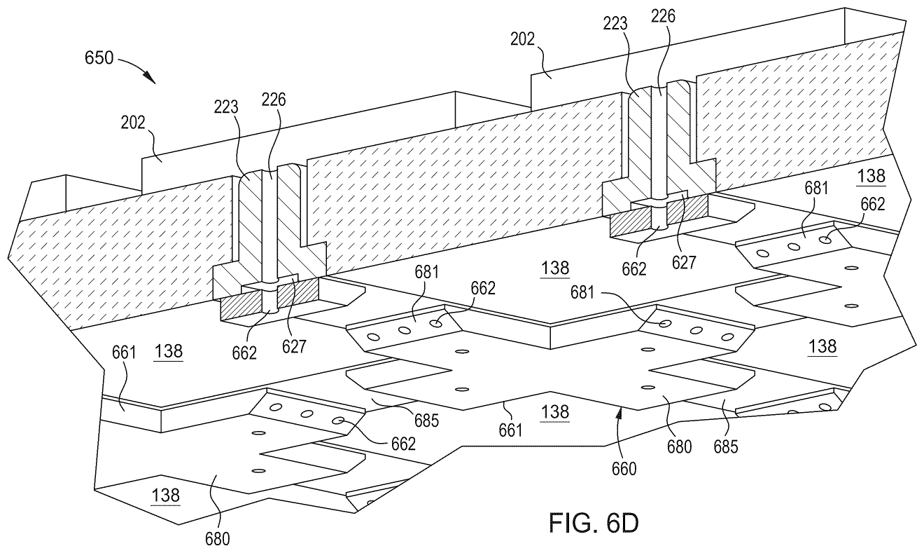

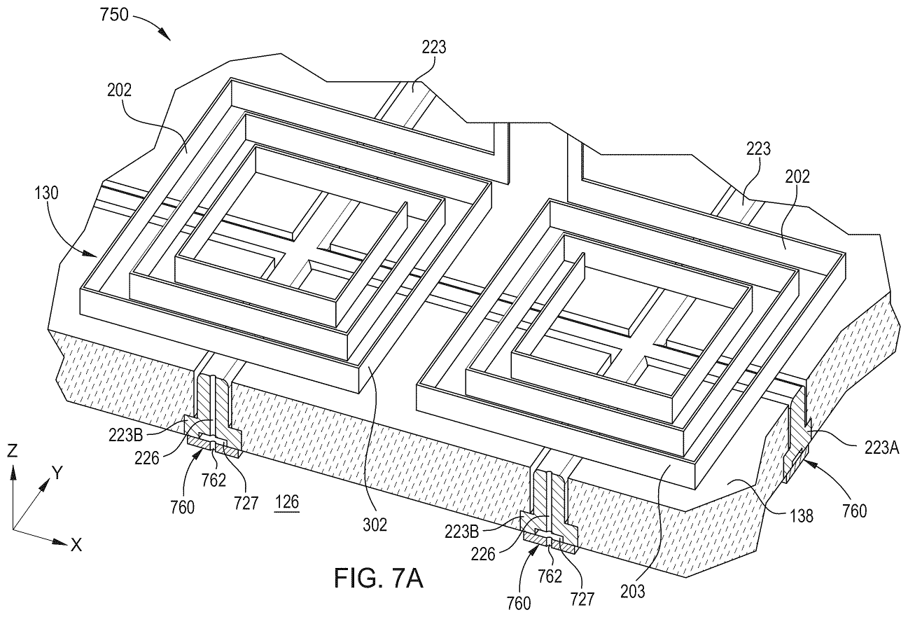

FIG. 6A illustrates a schematic, cross-sectional perspective view of a portion of an antenna array 650 with a beveled gas diffusion module 660 coupled to an interface member 223. FIG. 6B illustrates a schematic, bottom view of a portion of the antenna array 650 with the beveled gas diffusion module 660. FIG. 6C illustrates a schematic cross-sectional side view of a portion of the antenna array 650 with the beveled gas diffusion module 660. FIG. 6D illustrates a bottom perspective view of a portion of the antenna array 650 with the beveled gas diffusion module 660. The antenna array 650 may be used in place of the antenna array 250.

The beveled gas diffusion module 660 includes a body 661 having extensions 680. The extensions 680 extend along (e.g., adjacent to) the interface members 223. In some embodiments, the extensions 680 of adjacent beveled gas diffusion modules 660 are not in contact with one another, e.g., the adjacent extensions 680 form a passageway 685 between ends 681 of the adjacent extensions 680. Optionally, the ends 681 of the extensions 680 are beveled ends.

The beveled gas diffusion modules 660 are coupled to a bottom surface of the interface members 223. The beveled gas diffusion module 660 extends a second distance d₂ away from the lower surface of interface member 223 into the processing region 126. The second distance d₂ is less than about 6 mm, such as about 1 mm to about 6 mm.

The limited extension of the bottom surface of the beveled gas diffusion module 660 into the plasma processing region 126, the beveled ends 681, and the passageways 685 inhibit perturbations to the gas flow and disturbances to the boundary conditions required to generate a uniform plasma at a required RF power level within the processing region 126. Thus, the limited extensions of the beveled gas diffusion module 660 increases the uniformity of film thickness across the substrate 102.

The body 661 and extensions 680 include a plurality of gas diffusion holes 662. The gas ports 226 are configured to allow gases to flow into the processing region 126 via the beveled gas diffusion module 660 at predetermined flow rates. The beveled gas diffusion module 660 receives the gas from the gas ports 226 and diffuses the gas into the processing region 126 via the plurality of gas diffusions holes 662 to enable increased uniformity in gas distribution throughout the processing region 126. The interface member 223 further includes a plenum 627. The plenum 627 extends along the bottom surface of the interface member 223 at an interface of the bottom surface of the interface member 223 and the beveled gas diffusion module 660. The plenum 627 is configured to enable the distribution of the gas from the gas ports 226 to the gas diffusion holes 662.

In some embodiments, which may be combined with other embodiments, the body 661 includes split path diffusion holes, e.g., the body 661 includes a first path 668A extending from the gas ports 226 to a first diffusion hole 662A and a second path 668B extending from the gas ports 226 to a second diffusion hole 662B. The path length of the first path 668A and a second path 668B of the split path diffusion hole may be equal or may not be equal. The pattern and type of gas diffusion holes 662 are optimized to promote uniform deposition of films on the substrate 102. Each of the plurality of gas diffusion holes 662 further has a diameter. Controlling the path length and diameter of the plurality of gas diffusion holes 662 enables the gas flow required for deposition uniformity and other film property results.

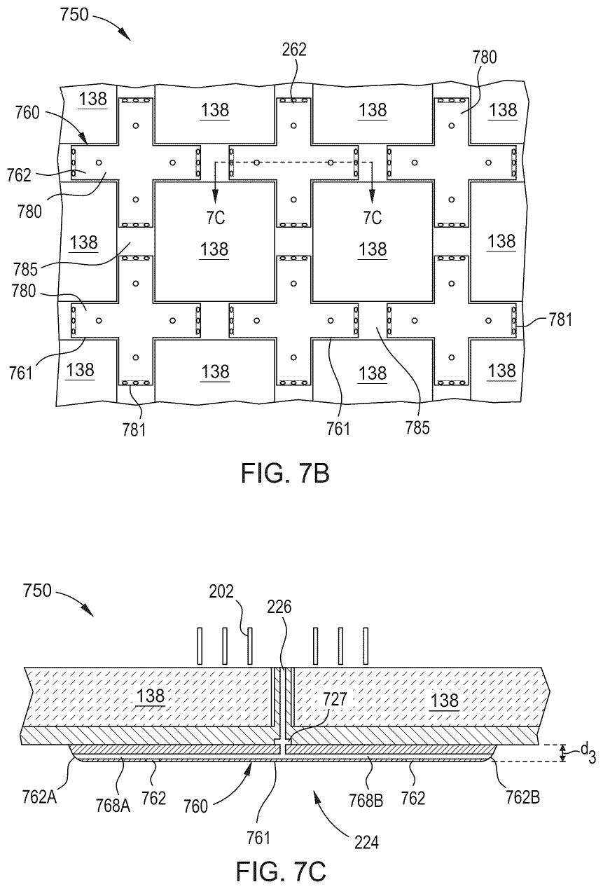

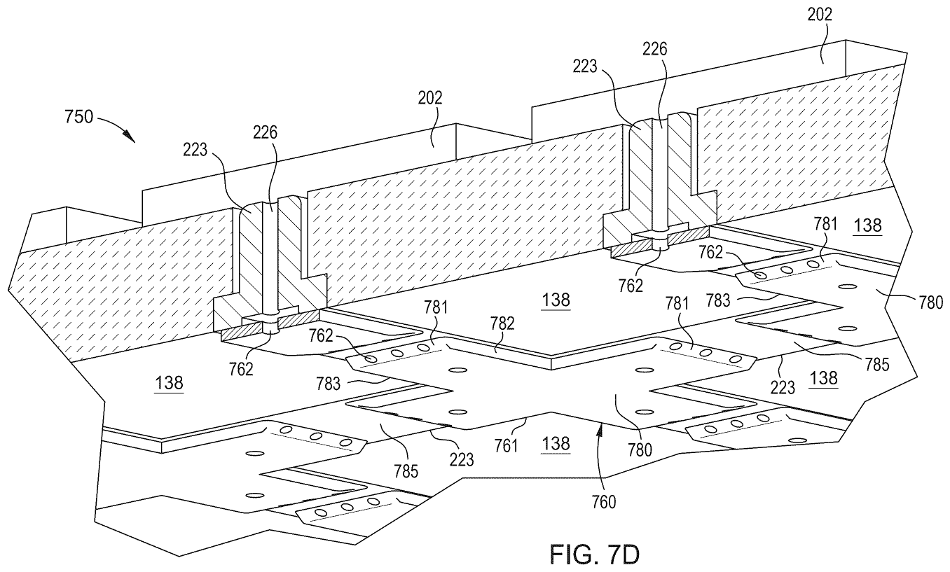

FIG. 7A illustrates a schematic, cross-sectional perspective view of a portion of an antenna array 750 with a rounded gas diffusion module 760 coupled to an interface member 223. FIG. 7B illustrates a schematic, bottom view of a portion of the antenna array 750 with the rounded gas diffusion module 760. FIG. 7C illustrates a schematic cross-sectional side view of a portion of the antenna array 750 with the rounded gas diffusion module 760. FIG. 7D illustrates a bottom perspective view of a portion of the antenna array 750 with the rounded gas diffusion module 760. The antenna array 750 may be used in place of the antenna array 250.

The rounded gas diffusion module 760 includes a body 761 having extensions 780. The extensions 780 extend long the interface members 223. In some embodiments, the extensions 780 of adjacent rounded gas diffusion modules 760 are not in contact with one another, e.g., the adjacent extensions 780 form a passageway 785 between ends 781 of the adjacent extensions 780. In some embodiments, the ends 781 of the extensions 780 are rounded ends and a first side 782 and second side 783 of the extensions 780 are rounded sides.

The rounded gas diffusion modules 760 are coupled to a bottom surface of the interface members 223. The rounded gas diffusion module 760 extends a third distance d₃ away from the lower surface of the interface member 223 into the processing region 126. The third distance d₃ is less than about 4 mm, such as about 1 mm to about 4 mm.

The limited extension of the bottom surface of the rounded gas diffusion module 760 into the plasma processing region 126, the rounded ends 781, rounded first side 782, rounded second side 783, and the passageways 785 inhibit perturbations to the gas flow and disturbances to the boundary conditions required to generate a uniform plasma at a required RF power level within the processing region 126. Thus, the limited extensions of the rounded gas diffusion module 760 increases the uniformity of film thickness across the substrate 102.

The body 761 includes a plurality of gas diffusion holes 762. The gas ports 226 are configured to allow gases to flow into the processing region 126 via the rounded gas diffusion module 760 at predetermined flow rates. The rounded gas diffusion module 760 receives the gas from the gas ports 226 and diffuses the gas into the processing region 126 via the plurality of gas diffusions holes 762 to enable increased uniformity in gas distribution throughout the processing region 126. The interface member 223 further includes a plenum 727. The plenum 727 extends along the bottom surface of the interface member 223 at an interface of the bottom surface of the interface member 223 and the rounded gas diffusion module 760. The plenum 727 is configured to enable the distribution of the gas from the gas ports 226 to the gas diffusion holes 762.

The body 761 includes split path diffusion holes, e.g., the body 761 includes a first path 768A extending from the gas ports 226 to a first diffusion hole 762A and a second path 768B extending from the gas ports 226 to a second diffusion hole 762B. The path length of the first path 768A and a second path 768B of the split path diffusion hole may be equal or unequal. The pattern and type of gas diffusion holes 762 are optimized to promote uniform deposition of films on the substrate 102. Each of the plurality of gas diffusion holes 762 further has a diameter. Controlling the path length and diameter of the plurality of gas diffusion holes 762 enables the gas flow required for deposition uniformity and other film property results.

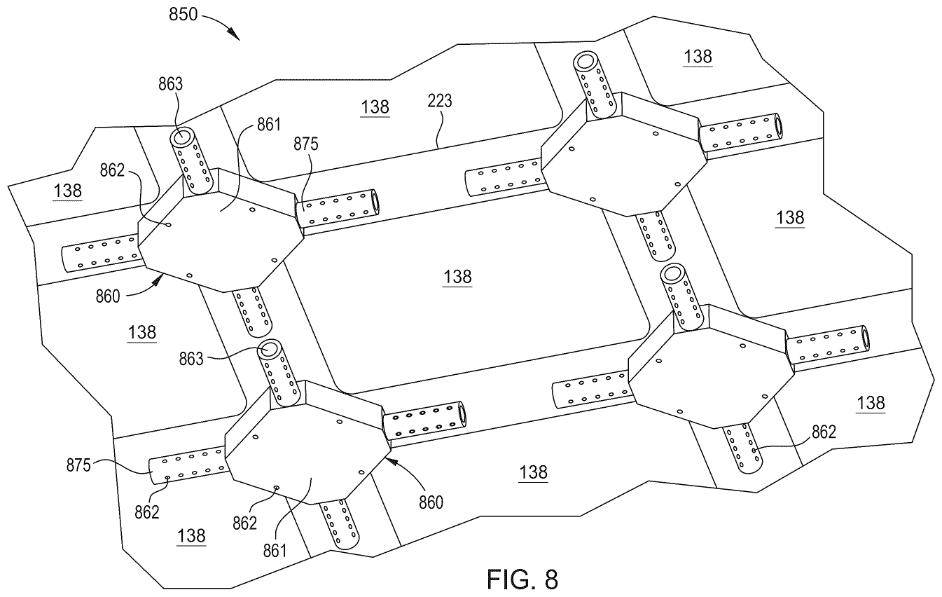

FIG. 8 illustrates a bottom perspective view of a portion of the antenna array 850 with the interface tube gas diffusion module 860 coupled to the interface member 223. The antenna array 850 may be used in place of the antenna array 250.

The interface tube gas diffusion module 860 include a body 861. The interface tube gas diffusion modules 860 are coupled to a bottom surface of the interface members 223. The interface tube gas diffusion module 860 extends a distance away from the interface member 223 into the processing region 126. The distance that the interface tube gas diffusion module 860 extends outward from the interface member 223 may be less than about 12 mm, such as less than about 6 mm, such as about 1 mm to about 6 mm. The limited extension of the bottom surface of the interface tube gas diffusion module 860 into the plasma processing region 126 inhibit perturbations to the gas flow and disturbances to the boundary conditions required to generate a uniform plasma at a required RF power level within the processing region 126. Thus, the limited extensions of the interface tube gas diffusion module 860 increases the uniformity of film thickness across the substrate 102.

The interface tube gas diffusion module 860 may further include interface gas diffusion tubes 875. The interface gas diffusion tubes 875 extend from the body 861 of the interface tube gas diffusion module 860 along the interface member 223. The interface gas diffusion tubes 875 include a plurality of gas diffusions holes 862 and an aperture 863. The gas diffusion holes 862 and the aperture 863 are optimized to promote uniform deposition of films on the substrate 102. The interface tube gas diffusion module 860 may be made of a non-magnetic material (e.g., non-paramagnetic or non-ferromagnetic material), such as an aluminum material (e.g., aluminum, aluminum oxide, aluminum nitride). The non-magnetic material forms an electrically grounded environment through which the gas may flow, which inhibits the formation of a parasitic plasma due to the lack an on electric field.

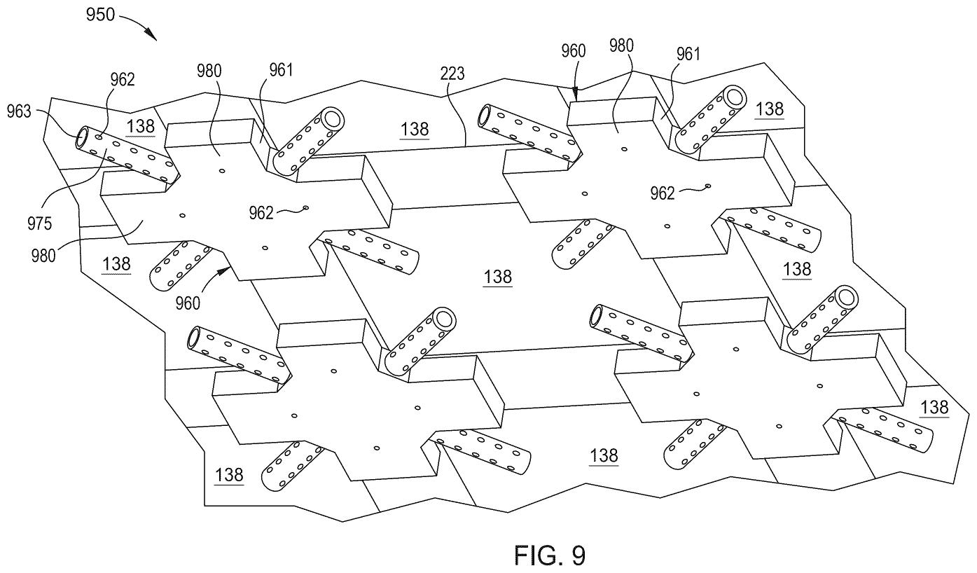

FIG. 9 illustrates a bottom perspective view of a portion of the antenna array 950 with the window tube gas diffusion module 960 coupled to the interface member 223. The antenna array 950 may be used in place of the antenna array 850.

The window tube gas diffusion module 960 includes a body 961 having extensions 980. The extensions 980 extend away from the body 961 along the interface members 223. The window tube gas diffusion module 960 are coupled to a bottom surface of the interface members 223. The window tube gas diffusion module 960 may further include window gas diffusion tubes 975. The window gas diffusion tubes 975 extend from the body 961 of the window tube gas diffusion module 960 towards the center of the dielectric window 138. The window gas diffusion tubes 975 extends an angle between 1° and 89°, such as between 30° and 65°, from the extensions 980. The gas diffusion holes 962 and the aperture 963 are optimized to promote uniform deposition of films on the substrate 102.

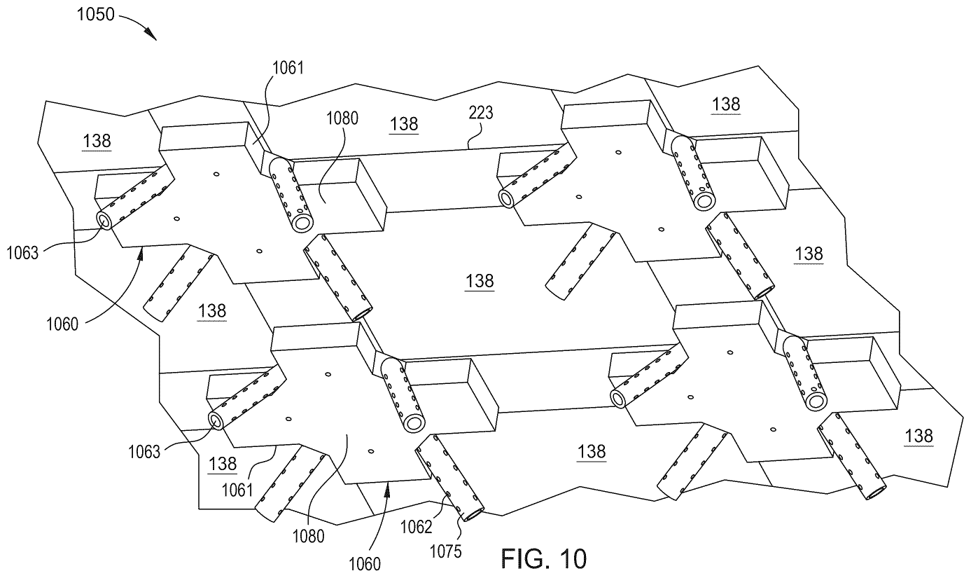

FIG. 10 illustrates a bottom perspective view of a portion of the antenna array 1050 with the processing region tube gas diffusion module 1060 coupled to the interface member 223. The antenna array 1050 may be used in place of the antenna array 850.

The processing region tube gas diffusion module 1060 includes a body 1061 and extensions 1080. The extensions 1080 extend away from the body 1061 along the interface members 223.

The processing region tube gas diffusion module 1060 may further include processing region gas diffusion tubes 1075. The processing region gas diffusion tubes 1075 extend downward from the body 1061 of the processing region tube gas diffusion module 1060 into the processing region 126 and towards the center of the dielectric window 138. The processing region gas diffusion tubes 1075 extends downward from the body 1061 of the processing region tube gas diffusion module 1060 and into the processing region 126 at an angle between 1° and 89°, such as between 30° and 65°. The processing region gas diffusion tubes 1075 extends from the body 1061 of the processing region tube gas diffusion module 1060 at an angle between 1° and 89°, such as between 30° and 65°, from the extensions 1080. The gas diffusion holes 1062 and the aperture 1063 are optimized to promote uniform deposition of films on the substrate 102.

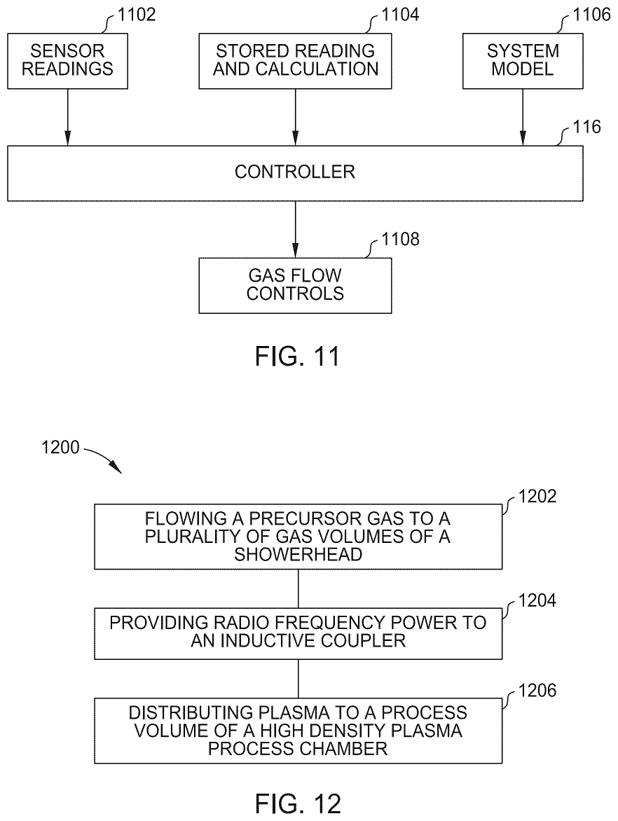

FIG. 11 illustrates a control schematic for use within the processing chamber 100. The controller 116 is part of a process system for storing instructions that, when executed, cause the process system to process a substrate within a processing chamber according to this disclosure. In one embodiment, the instructions cause the process system to process a substrate within a processing chamber by flowing a process gas through the plurality of interface members 223 having a gas port into a processing region, forming a plasma using a plurality of inductive couplers, and depositing the gas on the substrate. The processing chamber includes a plurality of sensors to facilitate deposition on the substrate, measure the deposition rate, and control a power supply, a temperature, and a gas flow rate. The controller 116 receives data or input from sensor readings 1102 from the sensors within the processing chamber 100. The controller 116 is equipped with or in communication with a system model 1106 of the processing chamber 100. The system model 1106 includes heating modules, gas flow modules, power modules, and deposition modules. The system model 1106 is a program configured to estimate or determined the gas flow, heating, deposition, and power within the processing chamber 100 throughout the process. The controller 116 is further configured to store readings and calculations 1104.

The readings and calculations 1104 include previous sensor readings 1102 as well as any other previous sensor readings within the processing chamber 100. The readings and calculations 1104 further include the stored calculated values from after the sensor readings 1102 are measured by the controller 116 and run through the system model 1106. Therefore, the controller 116 is configured to both retrieve stored readings and calculations 1104 as well as save readings and calculations 1104 for future use. Maintaining previous readings and calculations enables the controller 116 to adjust the system model 1106 over time to reflect a more accurate version of the processing chamber 100.

In embodiments described herein, the controller 116 includes a programmable central processing unit (CPU) that is operated with a memory and a mass storage device, an input control unit, and a display unit (not shown). The controller 116 monitors the precursor, process gas, and purge gas flow. Support circuits are coupled to the CPU for supporting the processor in a conventional manner. In some embodiments, the controller 116 includes multiple controllers 116, such that the stored readings and calculations 1104 and the system model 1106 are stored within a separate controller from the controller 116 which operations the processing chamber 100. In other embodiments, all of the system model 1106 and the stored readings and calculations 1104 are saved within the controller 116.

The controller 116 is configured to control the heating, power, deposition, and gas flow through the processing chamber 100 by controlling aspects of the gas flow controls 1108. The gas flow controls 1108 the process gas source, the purge gas source, and the exhaust pump. The controller 116 may also control the shaft 110 within the processing chamber 100.

The controller 116 is configured to adjust the output to each of the gas flow controls 1108 based off the sensor readings 1102, the system model 1106, and the stored readings and calculations 1104. The controller 116 includes embedded software and a compensation algorithm to calibrate deposition on the substrate 102. The deposition on the substrate 102 may be measured as the substrate leaves the processing chamber or between process operations to provide a reference for deposition rates measured using the sensors. The controller 116 may include a machine-learning algorithm and may use a regression or clustering technique. The algorithm is an unsupervised or a supervised algorithm.

FIG. 12 is a block flow diagram of a method 1200 of depositing films over a substrate 102. The method includes, in operation 1202, flowing a precursor gas to a processing region 126. The precursor gas flows into the processing region via an antenna array, e.g., antenna array 250, 550, 650, 750, 850, 950, or 1050.

In operation 1204, a radiofrequency power is provided to an inductive coupler disposed above the processing region 126. In operation 1206, plasma is distributed to a process region 126 of a high-density plasma processing chamber 100. The plasma has a plasma density of about 1×10¹⁰ cm⁻³ to about 10×10¹² cm⁻³ and each gas volume is maintained at a vacuum volume of about 10 mTorr to about 3 Torr. A film is deposited on a substrate, such as a rectangular substrate, the film is composed of silicon oxide, silicon nitride, silicon-oxide-nitride, or combinations thereof.

FIG. 13 illustrates a hexagonal antenna array 1350 having hexagonal antennas 1302. The hexagonal antenna array 1350 may be used in place of the antenna array 250. The hexagonal antenna 1302 configuration depicts one hexagonal antenna 1302 that can be arranged with adjacent hexagonal antennas 1302 having substantially the same configuration in a pattern across the lid assembly 106. The hexagonal antenna 1302 includes a conductor pattern that is a hexagonal spiral shape. Electrical connections include an electrical input terminal 1395A and an electrical output terminal 1395B.

The hexagonal antenna array 1350 includes interface members 1323 to form a grid to support a portion of the perimeter or the edge of the dielectric window 1338. Each interface member 1323 includes a ledge or shelf that supports a portion of the perimeter or an edge of the dielectric window 1338.

FIG. 14 illustrates a triangular antenna array 1450 having triangular antennas 1402. The triangular antenna array 1450 may be used in place of the antenna array 250. The triangular antenna 1402 configuration depicts one triangular antenna 1402 that can be arranged with adjacent triangular antennas 1402 having substantially the same configuration in a pattern across the lid assembly 106. The triangular antenna 1402 includes a conductor pattern that is a hexagonal spiral shape. Electrical connections include an electrical input terminal 1495A and an electrical output terminal 1495B.

The triangular antenna array 1450 includes interface members 1423 to form a grid to support a portion of the perimeter or the edge of the dielectric window 1438. Each interface member 1423 includes a ledge or shelf that supports a portion of the perimeter or an edge of the dielectric window 1438.

The hexagonal antenna array 1350 and triangular antenna array 1450 decrease the size of low ICP coupling zones. The low coupling zones exist in the area in which adjacent antennas meet. The low coupling zones exist is due to the change in the direction of current and the superposition of current between the antennas. Reducing the size of the low coupling zones increases the ICP uniformity. Further, the turning angle of the hexagonal antennas 1302 is lower (e.g., about 60°), reducing the current ripples along the peripheral direction of the antennas and thus increasing the ICP uniformity.

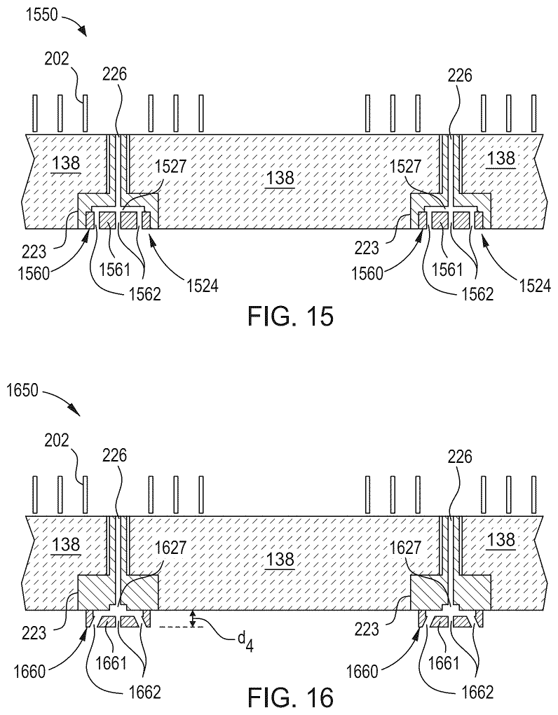

FIG. 15 illustrates a schematic cross-sectional side view of a portion of the antenna array 1550 with the gas diffusion module 1560 embedded in the interface member 223 and having perpendicular diffusion holes 1562. The gas diffusion module 1560 may be used in place of the gas diffusion module 260. The interface member 223 includes a channel 1524 and a plurality of gas ports 226. The channel 1524 is configured to house the gas diffusion module 1560. The gas diffusion module 1560 includes a body 1561 and a plurality of perpendicular diffusion holes 1562. The gas ports 226 are configured to allow gases to flow into the processing region 126 via the gas diffusion module 1560 at predetermined flow rates. The gas diffusion module 1560 receives the gas from the gas ports 226 and diffuses the gas into the processing region 126 via the plurality of perpendicular diffusions holes 1562 to enable increased uniformity in gas distribution throughout the processing region 126. The interface member 223 further includes a plenum 1527. The plenum 1527 extends along the channel 1524 at an interface of the channel 1524 and the gas diffusion module 1560. The plenum 1527 is configured to enable the distribution of the gas from the gas ports 226 to the perpendicular diffusion holes 1562. Each perpendicular diffusion hole 1562 extends perpendicular to the plenum 1527.

FIG. 16 illustrates a schematic cross-sectional side view of a portion of the antenna array 1650 with the gas diffusion module 1660 embedded in the interface member 223 and having angled gas diffusion hole 1662. The gas diffusion module 1660 may be used in place of the gas diffusion module 560. The gas diffusion modules 1660 are coupled to a bottom surface of the interface members 223. The gas diffusion module 1660 extends a first distance d₄ away from the interface member 223 into the processing region 126. The first distance d₄ is less than about 6 mm, such as about 1 mm to about 6 mm.

The body 1661 includes a plurality of gas diffusion holes 1662. The gas ports 226 are configured to allow gases to flow into the processing region 126 via the gas diffusion module 1660 at predetermined flow rates. The gas diffusion module 1660 receives the gas from the gas ports 226 and diffuses the gas into the processing region 126 via the plurality of gas diffusions holes 1662 to enable increased uniformity in gas distribution throughout the processing region 126. The gas diffusion module 1660 further includes a plenum 1627. The plenum 1627 is configured to enable the distribution of the gas from the gas ports 226 to the gas diffusion holes 1662. Each gas diffusion hole 1662 extends at an angle from about 10° to about 80° from the plenum 1627.

While the foregoing is directed to embodiments of the present disclosure, other and further embodiments of the disclosure may be devised without departing from the basic scope thereof, and the scope thereof is determined by the claims that follow.

What is claimed is:

1. An antenna array, comprising:
a plurality of inductive couplers, comprising a plurality of antennas disposed over a dielectric window;
a plurality of support members comprising an interface member configured to support the dielectric window, wherein the interface member comprises:
a plurality of gas ports; and
a channel;
a plurality of gas diffusion modules disposed within the channel, comprising:
a body; and
a plurality of gas diffusion holes.

2. The antenna array of claim 1, wherein the interface member further comprises:
a plenum extending along the channel at an interface of the channel and the plurality of gas diffusion modules, wherein the plenum is configured to enable a distribution of a process gas from the gas ports to the gas diffusion holes.

3. The antenna array of claim 2, wherein the plurality of gas diffusion modules extend less than about 4 mm past a lower surface of the interface member.

4. The antenna array of claim 2, wherein the plurality of gas diffusion modules do not extend past a lower surface of the interface member.

5. The antenna array of claim 1, wherein the interface member comprises a non-magnetic material.

6. The antenna array of claim 5, wherein the non-magnetic material includes an aluminum material.

7. The antenna array of claim 1, wherein the plurality of gas diffusion modules are coupled to the interface member.

8. An antenna array, comprising:
a plurality of inductive couplers, comprising a plurality of antennas disposed over a dielectric window;
a plurality of support members comprising an interface member configured to support the dielectric window, wherein the interface member comprises:
a plurality of gas ports; and
a plurality of gas diffusion modules coupled to the interface member and extending less than about 12.1 mm past a lower surface of the interface member, the plurality of gas diffusion modules comprising:
a body comprising:
a plurality of gas diffusion holes.

9. The antenna array of claim 8, wherein the body further comprises extensions extending adjacent to the interface member.

10. The antenna array of claim 9, wherein:
the extensions include a beveled edge; and
the body extends less than about 6 mm past a lower surface of the interface member.

11. The antenna array of claim 9, wherein:
the extensions include a rounded edge; and
the body extends less than about 4 mm past a lower surface of the interface member.

12. The antenna array of claim 8, wherein extensions of adjacent gas diffusion modules define a passageway.

13. The antenna array of claim 8, wherein the interface member comprises a non-magnetic material.

14. The antenna array of claim 13, wherein the non-magnetic material includes an aluminum material.

15. An antenna array, comprising:
a plurality of inductive couplers, comprising a plurality of antennas disposed over a dielectric window;
a plurality of support members comprising an interface member configured to support the dielectric window, wherein the interface member comprises:
a plurality of gas ports; and
a plurality of gas diffusion module coupled to the interface member, comprising:
a body; and
gas diffusion tubes comprising:
a plurality of gas diffusion holes.

16. The antenna array of claim 15, wherein the gas diffusion tubes further comprise an aperture.

17. The antenna array of claim 15, wherein the gas diffusion tubes adjacent to the interface member.

18. The antenna array of claim 15, wherein the body further comprises extensions extending adjacent to the interface member.

19. The antenna array of claim 18, wherein:
the gas diffusion tubes extend from the body of the gas diffusion module and into a processing region at an angle between 30° and 65°; and
the gas diffusion tubes extend from the body of the gas diffusion module at an angle between 30° and 65° from the extensions.

20. The antenna array of claim 18, wherein the gas diffusion tubes extend from the body of the gas diffusion module at an angle between 30° and 65° from the extensions.
